(19) United States
(12) Patent Application Publication
(10) Pub. No.: US 2026/0173536 A1
(43) Pub. Date: Jun. 18, 2026

(54) ELECTROSTATIC DISCHARGE BIPOLAR DEVICE WITH COLLECTOR AND EMITTER BALLASTING

(71) Applicant: INTERNATIONAL BUSINESS MACHINES CORPORATION, ARMONK, NY (US)

(72) Inventors: Mahender Kumar, Clifton Park, NY (US); Anthony I-Chih Chou, Guilderland, NY (US); Ravikumar Ramachandran, Pleasantville, NY (US); Robert Gauthier, Williston, VT (US)

(21) Appl. No.: 18/983,194

(22) Filed: Dec. 16, 2024

(51) Int. Cl. H10D 89/60; H01L 21/762; H10D 10/01; H10D 10/60; H10D 62/10; H10D 64/23

(52) U.S. Cl. CPC H10D 89/711; H10D 10/60; H10D 62/121; H10D 64/231; H10W 10/014; H10W 10/17; H10D 10/061

(57) ABSTRACT

A semiconductor device includes a base, an emitter, a collector between the base and the emitter, a well region below the base, the emitter and the collector, and an isolating layer extended horizontally and at least partially isolating the well region from the collector and the emitter.

### BACKGROUND

### Technical Field

The present disclosure generally relates to semiconductors, and more particularly, to electrostatic discharge bipolar device with collector and emitter ballasting structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a base, an emitter, a collector between the base and the emitter, a well region below the base, the emitter and the collector, and an isolating layer extended horizontally and at least partially isolating the well region from the collector and the emitter.

In one embodiment, the isolating layer, the well region, the collector and the emitter form a junction, and the junction is configured to act as at least part of a lateral bipolar emitter and lateral bipolar collector for local ballasting and series resistance.

In one embodiment, the junction is further configured to be part of a source/drain region of a transistor for local ballasting and series resistance.

In one embodiment, each of the based, collector and emitter includes a set of gate regions, a doped region between the set of gate regions, and a contact over the doped region.

In one embodiment, each of the base, collector and emitter includes a set of nanosheet channels extended horizontally across a gate region.

In one embodiment, the set of nanosheet channels are made of alternating layers of silicon and silicon germanium.

In one embodiment, the semiconductor device includes shallow trench isolation (STI) below gate regions of the base, collector and emitter adjacent to each other, and a substrate below the well region.

In one embodiment, the semiconductor device is an electro-static discharge (ESD) lateral NPN device, or an EDS lateral PNP device.

According to an embodiment, a method for fabrication of a semiconductor device includes forming a base, forming an emitter, forming a collector between the base and the emitter, forming a well region below the base, the emitter and the collector, and forming an isolating layer extended horizontally and at least partially isolating the well region from the collector and the emitter.

In one embodiment, the method includes forming a junction via the isolating layer, the well region, the collector and the emitter. The junction is configured to act as at least part of a lateral bipolar emitter and lateral bipolar collector for local ballasting and series resistance.

In one embodiment, the junction is part of a source/drain region of a transistor for local ballasting and series resistance.

In one embodiment, forming each of the based, collector and emitter includes forming a set of gate regions, forming a doped region between the set of gate regions, and forming a contact over the doped region.

In one embodiment, forming each of the base, collector and emitter includes forming a set of nanosheet channels extended horizontally across a gate region.

In one embodiment, the set of nanosheet channels are made of alternating layers of silicon and silicon germanium.

In one embodiment, the method includes forming shallow trench isolation (STI) below gate regions of the base, collector and emitter adjacent to each other, and forming a substrate below the well region.

In one embodiment, the semiconductor device is an electro-static discharge (ESD) lateral NPN device, or an EDS lateral PNP device.

According to an embodiment, a semiconductor device includes a well region on the backside of the semiconductor device, and an isolating layer extended horizontally and at least partially isolating the well region from the frontside of the semiconductor device. The isolating layer and the well region, form a junction configured to act as at least part of a lateral bipolar emitter and lateral bipolar collector for local ballasting and series resistance.

In one embodiment, the junction is further configured to be part of a source/drain region of a transistor for local ballasting and series resistance.

In one embodiment, the semiconductor device includes a base, an emitter, and a collector between the base and the emitter. The base, the collector and the emitter are located on the frontside of the semiconductor device.

In one embodiment, each of the based, collector and emitter includes a set of gate regions, a doped region between the set of gate regions and a contact over the doped region.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a conventional planar electrostatic discharge N-field effect transistor (ESDNFET) without ballasting resistance on source/drain regions.

FIG. 1B illustrates a top view of the device shown in FIG. 1A.

FIG. 1C illustrates an I-V graph of the device shown in FIG. 1A.

FIGS. 2A-2B illustrate a conventional ESD lateral NPN STI bound, ESDLNPN_STI) and the relationship between the current and voltage during an ESD event.

FIG. 3A illustrates an electrostatic discharge LNPN shallow trench isolation-bound (ESDLNPN_STI) with ballasting resistance on doped regions, in accordance with some embodiments.

FIG. 3B illustrates an electrostatic discharge N-field effect transistor (ESDNFET) with ballasting resistance on doped regions, in accordance with some embodiments.

FIG. 3C illustrates an I-V graph of the device shown in FIG. 3A.

FIG. 4 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

The concepts herein relate to electrostatic discharge (ESD) devices. ESD devices are integral in safeguarding electronic circuits from abrupt electrical discharges that can cause damage. These devices typically feature numerous fingers or blocks of diffusions, which are segments of semiconductor material modified by diffusion processes to achieve specific electrical characteristics. To create an ESD device designers often connect hundreds or thousands of these blocks in parallel. In conventional ESD devices, particularly those employing architectures with hundreds of fingers (conductive paths within the device) arranged in a matrix of columns and rows, the lack of uniform current distribution can lead to significant performance issues. Typically, without adequate ballasting resistance, only one or two fingers may activate during an ESD event, leading to suboptimal dissipation of the electrostatic discharge and a consequent low failure threshold of the device.

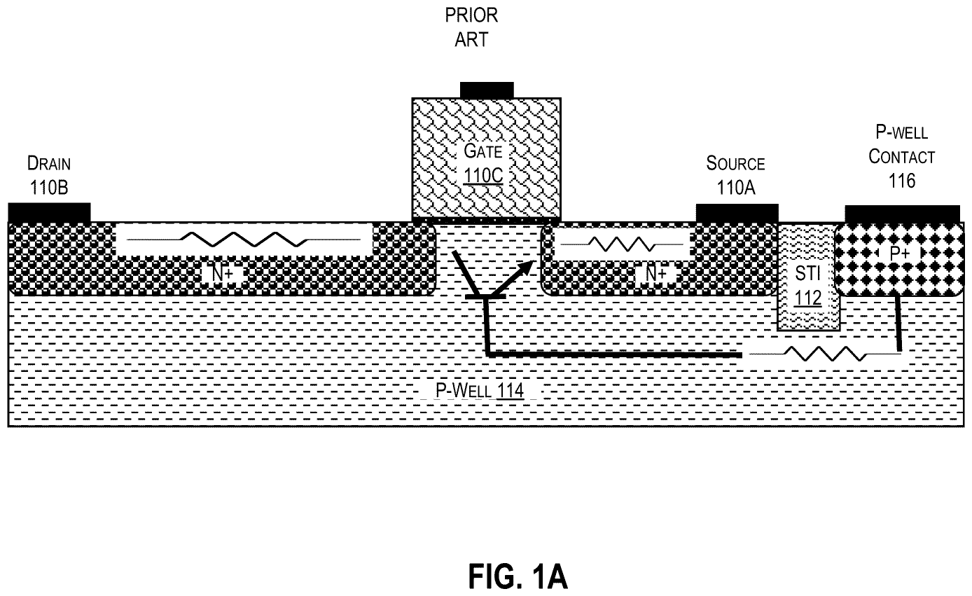

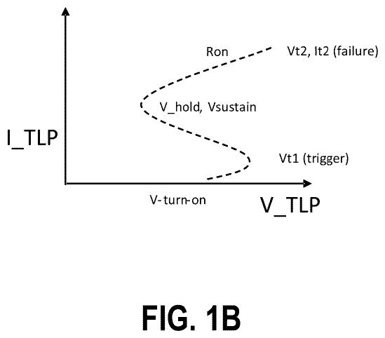

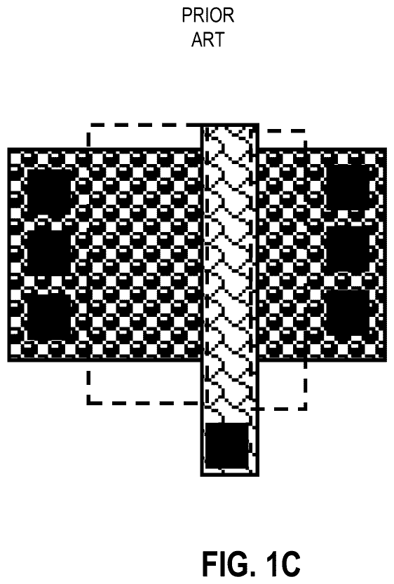

FIGS. 1A-1B illustrate a conventional planar ESDNFET with ballasting resistance on source/drain regions. The conventional planar ESDNFET can include a source 110A, a drain 110B, a gate 110C, a shallow trench isolation, STI 112, a P-well 114 and a P-well contact 116. In a typical layout, the conventional planar NFET can include multiple columns and rows of fingers, with the width of each finger ranging from about 1 micrometer to about 20 micrometers, and the total width of the planar NFET ranging from about 200 micrometers to about 500 micrometers. A common issue in conventional devices such as the ESDNFET shown in FIG. 1A is uneven current distribution which leads to the activation of only a select few fingers, potentially compromising the device's integrity and effectiveness. In traditional ESDNFET device configurations, the resistance in the drain 110B (collector) and source 110A (emitter) regions ensures that the current is evenly spread across the width of the device. However, achieving uniform activation of all fingers simultaneously has posed challenges. Typically, a single finger within the array triggers first due to variations in threshold voltage or other localized conditions, which can lead to the premature failure of the device under high-stress conditions. FIG. 1B shows a top view of the ESDNFET device shown in FIG. 1A.

FIG. 1C illustrates an I-V graph for the device shown in FIG. 1A. The planar ESD NFET with ballasting resistance on its drain and source terminals typically exhibits a characteristic I-V curve that can be divided into four regions of operation as it responds to an increasing voltage or transient event. This transistor structure is commonly employed for electrostatic discharge (ESD) protection due to its ability to clamp high-voltage spikes and safely divert excessive current. To ensure proper triggering and uniform current distribution across multiple parallel device “fingers,” a certain amount of series resistance is introduced at the drain and source terminals, often referred to as ballasting resistance.

In the initial stages, before the transistor fully activates, it goes through several operational phases defined by its current (I) versus voltage (V) behavior, key parameters, and associated challenges. 1. Leakage and pre-turn-on region: At low applied voltages, the transistor remains off, and only a minimal leakage current flows. In this region, the device is below its trigger voltage (V-trigger or Vt1) and behaves as a simple off-state transistor, ideally isolating the protected circuitry from any undesired current. Since the voltage has not yet reached a critical level, the device shows only negligible conduction. The current in this phase is extremely low and primarily determined by subthreshold leakage mechanisms and any small leakage paths. No significant ESD protection is actively provided here; it is essentially a standby condition.
2. Trigger/turn-on region: As the applied voltage rises and reaches the trigger voltage Vt1, an avalanche breakdown or a parasitic bipolar transistor action within the NFET structure initiates. This event dramatically increases the device's conduction, causing it to enter a snapback region. Once triggered, the voltage across the device actually decreases slightly due to this snapback phenomenon, even though current is increasing. This rapid turn-on ensures that the device can clamp the ESD spike by providing a low-resistance path to divert the surge of current. The ballasting resistance on the drain and source comes into play here: it helps spread the current along the width of the transistor, preventing localized hotspots. At this stage, only one finger (one parallel section of the transistor) may trigger first, so careful design is needed to ensure that subsequent fingers also turn on and share the current.
3. Holding/sustaining region: After the device has triggered, it settles into a holding regime where it sustains current conduction at a relatively stable voltage known as the holding voltage. The slope of the I-V curve in this region is determined by the effective on-resistance (Ron) of the device. This on-resistance is influenced by the transistor's geometry, doping, and the introduced ballasting resistors. The challenge is to strike a balance with Ron. If Ron is too low, the first triggered finger will carry most of the current without significantly increasing voltage, making it less likely for other fingers to trigger and share the load. This single-finger conduction can lead to localized heating and potential failure of that finger. On the other hand, if Ron is high enough, the device's voltage will rise as current increases, allowing it to approach Vfail (Vt2) before a single finger can fail. This rise in voltage encourages adjacent fingers to reach their own trigger conditions, turning on more uniformly and distributing current evenly across the entire transistor width. When done correctly, all fingers conduct simultaneously, reducing the stress on any one portion of the device and improving its overall robustness.

Another parameter to consider in this region is the load capacitance (Cload). The external circuitry and interconnects that the ESD protection device connects to often present a capacitive load. This capacitance can influence transient response and the dynamic behavior of the device during fast ESD events. The interplay between Cload and the transistor's Ron affects how quickly the voltage and current settle in the holding region. 4. Failure region: If the current continues to increase beyond sustainable levels or if the voltage surpasses Vfail (also known as Vt2), the device enters the failure region. At this point, the transistor's materials, junctions, or contacts undergo irreversible damage due to excessive thermal energy or current density. Failure might be in the form of junction meltdown, contact spiking, metal line electromigration, or oxide breakdown. The parameter Ifail (It2) represents the current at which this failure occurs. The presence of ballasting resistance and the correct design of the transistor structure are critical in preventing the device from entering this destructive regime under normal ESD event conditions.

A primary challenge in designing such an ESD NFET for multi-finger configurations is ensuring that not just a single finger handles all the current. Without sufficient series resistance, a single finger can trigger and conduct the entire ESD current, pushing it rapidly toward failure before other fingers can turn on. By introducing enough resistance in the drain/source regions, the I-V characteristic allows the voltage to climb sufficiently after the first finger triggers, approaching Vt2 and prompting other fingers to trigger as well. This coordinated triggering ensures current spreading across the transistor's width, improving the device's ability to handle high ESD currents without localized failure.

In essence, the I-V graph of a planar ESD NFET with ballasting resistance highlights a journey from near-zero leakage current (Region 1), through a sudden trigger and snapback (Region 2), into a stable holding regime where multiple fingers conduct uniformly (Region 3), and finally reaching a catastrophic failure mode if limits are exceeded (Region 4). By carefully tuning the ballasting resistance and the on-resistance, designers can craft a robust ESD protection element that effectively clamps high-voltage spikes and survives many stressful transient events without damage.

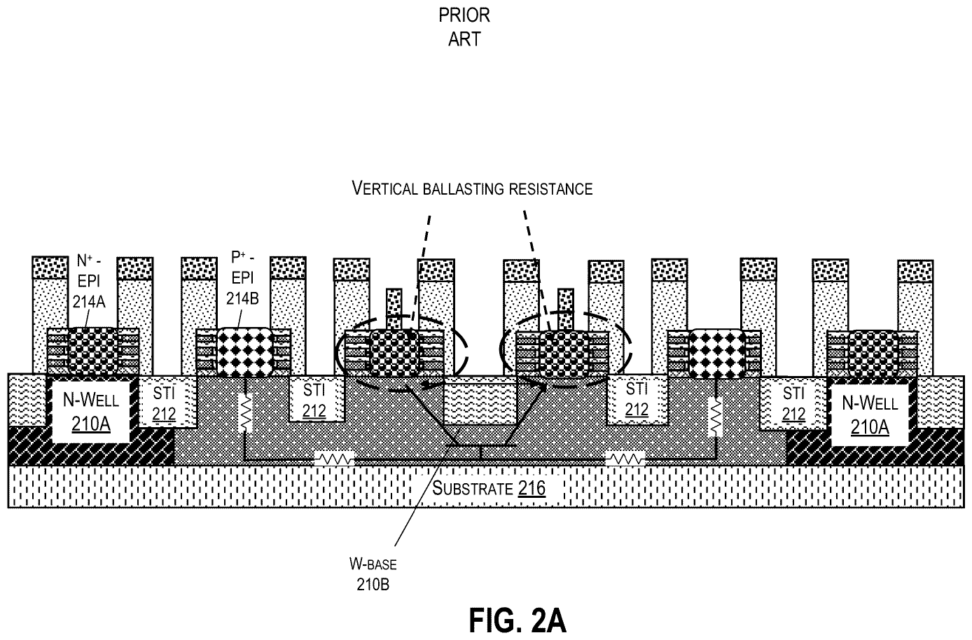

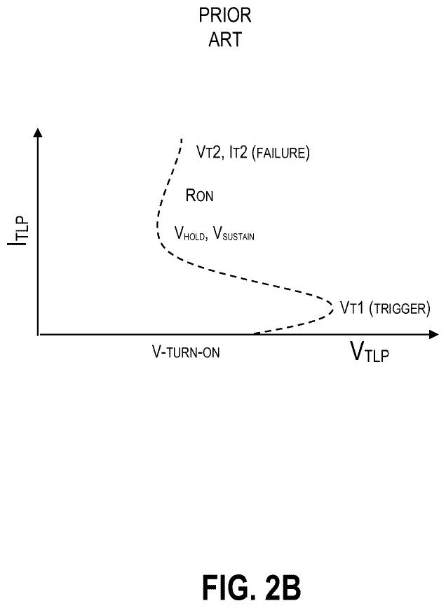

FIGS. 2A-2B illustrate a conventional ESD lateral NPN STI bound, ESDLNPN_STI) and the relationship between the current and voltage during an ESD event. The conventional ESDLNPN_STI can include an N-well 210A, a base, WBase 210B, STI 212, collectors and emitters, N-epi 214A and P-epi 214B, and a substrate 216. In a conventional ESDLNPN_STI, or a conventional ESDLNPN, ESDLPNP, ESDNFET, and ESDPFET configurations, the traditional designs often incorporate ballasting resistance in a vertical orientation through the epitaxial layer, N-epi 214A and/or P-epi 214B, of the collector and emitter. However, the vertical ballasting restricts the amount of epitaxial material that can be utilized, thereby constraining the effectiveness of the resistance. Thus, the ballasting resistance extends only vertically and not horizontally through the emitter and collector regions. FIG. 2B shows the current and voltage during four stages of operations including leakage/pre-turn on 1, trigger/turn on 2, holding/sustaining 3, and failure 4. As can be seen, the voltage increases from turn on voltage (V-turn-on) to trigger voltage (Vt1), at which point the voltage sharply decreases to the holding/sustaining voltage (V_hold/Vsustain). The voltage then slightly increases again until the failure occurs at which point the voltage reaches failure voltage (Vt2).

In electrostatic discharge (ESD) protection structures, particularly ESD field-effect transistors (FETs) and lateral bipolar devices, one important design challenge is ensuring that the transient current resulting from an ESD event is distributed uniformly across all the parallel “fingers” of the device. A finger here refers to one segment or unit cell of the transistor or bipolar structure arranged in parallel with many identical segments. Each finger forms its own conduction channel (for a FET) or conduction path (for a bipolar transistor) when the device is triggered to protect against the ESD surge. Without deliberate design measures, when the ESD event occurs and a large current spike is applied, only a small subset of these fingers—perhaps just one or two—can trigger into a conducting state first. This uneven triggering can happen because of slight natural variations in doping, local temperature differences, or minor geometric non-uniformities across the chip. Once a single finger starts conducting, it tends to draw even more current due to positive feedback mechanisms such as local heating and reduced resistance. This phenomenon leads to a situation known as “current crowding,” where one or two fingers are forced to carry the majority of the ESD current. Because these fingers are not designed to handle the full current load alone, they can fail very quickly, often as soon as they are stressed beyond their safe operating limits. This early failure limits the overall ESD robustness of the device and defeats the purpose of having many parallel paths.

To address this problem, disclosed semiconductor integrates “ballasting resistance” into the drain (acting like a collector in a bipolar sense) and source (acting like an emitter) regions of each finger. Ballasting involves intentionally adding some level of series resistance into the conduction path. This can be achieved by carefully controlling the doping concentration in certain regions, introducing lightly doped drain/source extensions, or by adding dedicated resistor structures. Thus, if one finger starts to conduct more current than its neighbors, the series resistance in that finger will cause a local voltage increase. This rise in local voltage discourages further current concentration in that finger alone and simultaneously encourages adjacent fingers to trigger. As a result, the current is more evenly distributed across all the fingers.

In a large ESD device, it is not uncommon to have hundreds, or even thousands, of these transistor or bipolar “fingers” arranged in a matrix of rows and columns. Each finger is nominally identical, and together they form a high-capacity ESD protection structure. Without proper ballasting, one could never fully leverage this parallel arrangement because the initial finger(s) to trigger would quickly fail and never allow the rest of the device to turn on. B y ensuring that every finger has just enough resistance, the device is forced to share current among all available fingers. This load balancing mechanism allows for a much higher total failure current (the current that the device can handle before it permanently breaks down). As a result, the ESD device can be made smaller while still meeting the required ESD robustness criteria, because the current is uniformly spread across many conduction paths rather than concentrated in one.

Ultimately, integrating ballasting resistance into the drain and source (or collector and emitter) regions is a proven technique to enhance current uniformity and reliability in ESD protection devices. This technique ensures that all fingers participate in conducting the ESD current event, thereby increasing the device's total current-handling capability, improving its failure threshold, and enabling more efficient usage of silicon area.

In view of the above considerations, disclosed is an electrostatic discharge bipolar device with collector and emitter ballasting. The disclose device can further be a nanosheet ESD bipolar device that leverages thin, sheet-like semiconductor channels known as nanosheets. These nanosheets are engineered through material deposition and lithographic techniques to form compact, three-dimensional transistor-like elements. Unlike traditional bipolar junction transistors, which have relatively thicker and more bulk-like semiconductor layers, nanosheet devices can achieve finer control over doping profiles, junction depths, and material composition due to their ultra-thin geometries and carefully engineered interfaces. When adapted for ESD protection, the disclosed bipolar device, the ultrathin channels improve response times and potentially offer more controlled conduction pathways in the ESD event.

The disclosed nanosheet ESD bipolar device with collector and emitter ballasting combines the fast, high-current conduction properties of bipolar technologies with the control over geometry and material properties that nanosheet architectures provide. By adding ballasting at both collector and emitter terminals, the disclosed device achieves a balanced, efficient, and robust ESD response.

Accordingly, the teachings herein provide methods and systems of an electrostatic discharge bipolar device with collector and emitter ballasting. The techniques described herein may be implemented in a number of ways. Example implementations are provided below with reference to the following figures.

### Example an Electrostatic Discharge Bipolar Device With Collector and Emitter Ballasting Structure

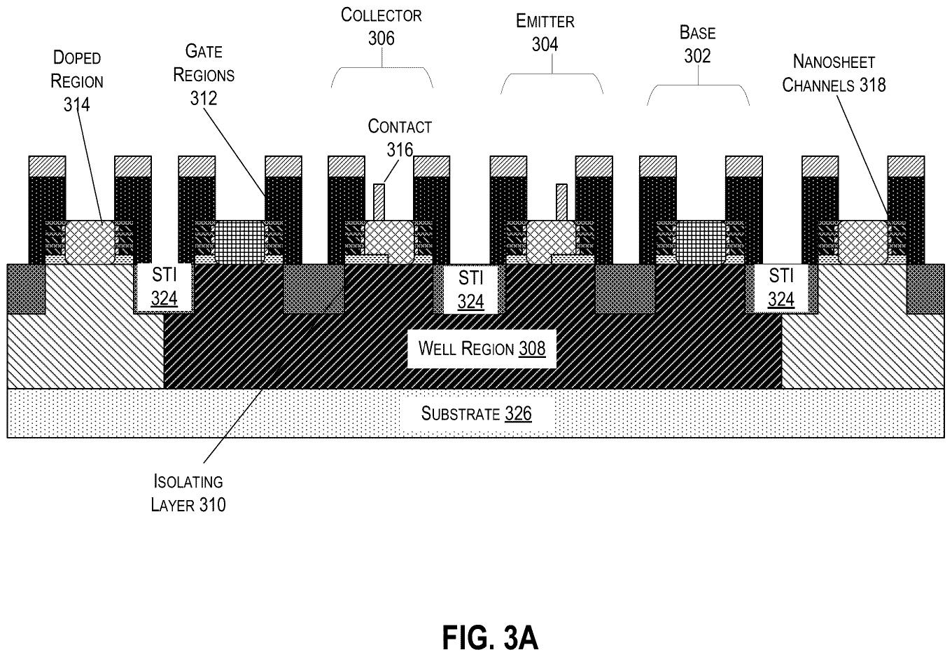

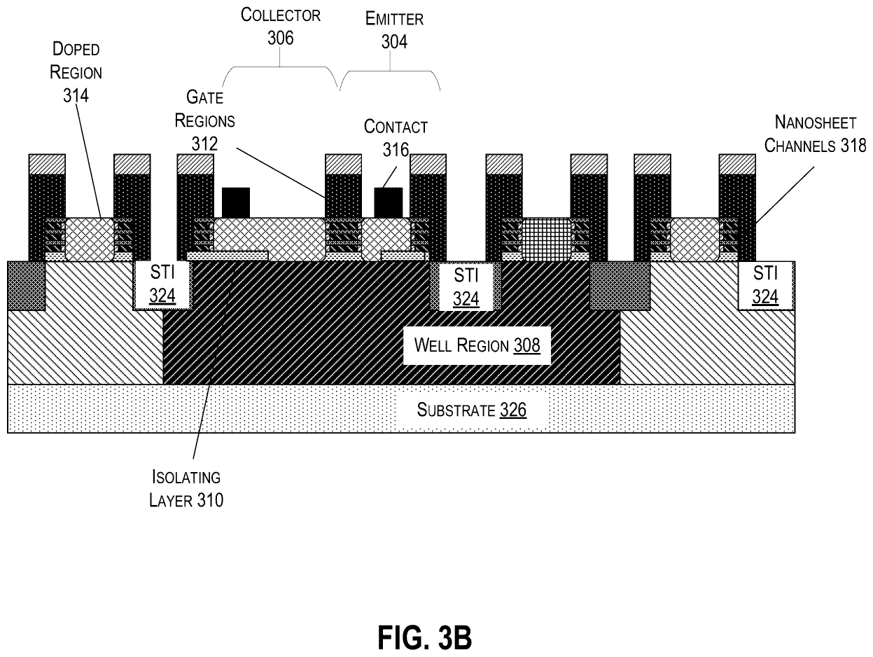

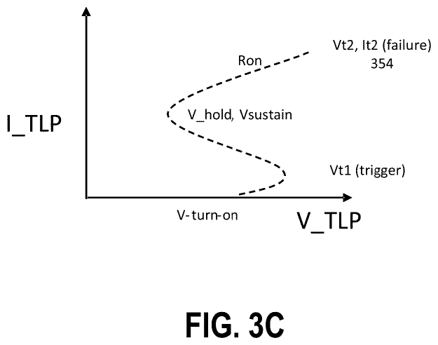

Reference now is made to FIG. 3A, which are simplified cross-sections view of a semiconductor device, consistent with an illustrative embodiment. In some embodiments, the semiconductor device includes a base 302, an emitter 304, and a collector 306 arranged such that the collector 306 is positioned between the base 302 and the emitter 304. The term “base”, as used herein, refers to a semiconductor region configured to control the flow of charge carriers between the emitter 304 and the collector 306. The “emitter” is a semiconductor region that injects charge carriers into the base 302, and the “collector” is a semiconductor region that collects these charge carriers after they traverse the base 302. By providing a defined spatial relationship among the base 302, emitter 304, and collector 306, the semiconductor device can function as a transistor-like structure capable of amplifying or switching electrical signals.

In some embodiments, a well region 308 is located below the base 302, the emitter 304, and the collector 306. The term “well region” refers to a doped portion of the semiconductor substrate that establishes a controlled conduction type (either N-type or P-type). The well region 308 forms the foundational layer on which the transistor elements are built, ensuring proper junction formation and enabling stable device operation. The doping profile of the well region 308 can be finely tuned to achieve desired electrical characteristics, such as threshold voltages and current handling capability.

In some embodiments, an isolating layer 310 extends horizontally and at least partially isolates the well region 308 from the collector 306 and the emitter 304. The isolating layer 310 can be a dielectric material, such as an oxide or nitride, inserted to prevent direct electrical conduction between certain semiconductor regions. By providing lateral isolation, the isolating layer 310 helps define current flow paths, reduce leakage currents, and improve the device's overall reliability. This isolation is important for ensuring that undesired conductive paths do not form and that current is channeled through intended junctions only.

In some embodiments, the isolating layer 310, the well region 308, the collector 306, and the emitter 304 form a junction configured to act, at least in part, as a lateral bipolar emitter and a lateral bipolar collector. Here, the phrase “lateral bipolar emitter” and “lateral bipolar collector” can refer to structures arranged to provide a lateral flow of charge carriers, thus creating a lateral bipolar junction transistor effect. Such lateral bipolar structures can provide local ballasting and series resistance, allowing more uniform current distribution across the device. This uniformity is especially beneficial in devices designed for electrostatic discharge (ESD) protection, where even current sharing prevents localized heating and premature failure.

In some embodiments, this junction is further configured to be part of a source/drain region of a transistor for local ballasting and series resistance. The source/drain region can be heavily doped semiconductor regions that form the terminals of a field-effect transistor (FET) channel. By integrating this junction into the source/drain region, the device can achieve enhanced current uniformity and improved ESD robustness, as the controlled resistance introduced by these regions helps manage current flow and prevents current crowding in any single portion of the device.

In some embodiments, each of the base 302, the collector 306, and the emitter 304 includes a set of gate regions 312, a doped region 314 between the set of gate regions 312, and a contact 316 over the doped region 314. The gate regions 312 can be conductive or semiconductive structures, commonly formed from polysilicon or metal, that modulate charge carrier flow by applying electric fields. The doped region 314 can be a semiconductor area enriched with specific dopants to alter conductivity, while the contact 316 is a metallization or conductive layer that provides electrical connection between the doped region 314 and external circuitry. Together, these elements form transistor substructures that can be connected in various configurations to achieve desired electrical functions.

In some embodiments, each of the base 302, collector 306, and emitter 304 further includes a set of nanosheet channels 318 extended horizontally across the gate regions 312. The nanosheet channels 318 can be extremely thin semiconductor layers, often on the order of a few nanometers, engineered to form conduction paths beneath the gate regions 312. These nanosheets enable precise electrostatic control and can significantly enhance device performance by reducing short-channel effects and improving carrier mobility.

In some embodiments, the set of nanosheet channels 318 is made of alternating layers of silicon and silicon germanium. By stacking alternating layers of silicon and silicon germanium, channels with tailored electrical characteristics can be formed, such as increased hole or electron mobility, enabling more efficient transistor operation.

In some embodiments, the semiconductor device further comprises shallow trench isolation, STI 324. below gate regions 312 of the base 302, collector 306, and emitter 304 adjacent to each other, and a substrate 326 below the well region 308. The STI 324 can be insulating trenches formed in the semiconductor to electrically isolate neighboring devices or transistor fingers. The substrate 326 is the foundational semiconductor wafer or layer upon which all other structures are formed. By including STI 324 and substrate 326, the device achieves robust isolation, reduced crosstalk, and stable mechanical support for the entire stack of nanosheets, doped regions, and gate regions.

While FIG. 3A illustrates an electrostatic discharge LNPN shallow trench isolation-bound (ESDLNPN_STI) with ballasting resistance on doped regions, in accordance with some embodiments, FIG. 3B illustrates an electrostatic discharge N-field effect transistor (ESDNFET) with ballasting resistance on doped regions, in accordance with some embodiments.

In some embodiments, the semiconductor device is an electro-static discharge (ESD) lateral NPN device or an ESD lateral PNP device. The ESD lateral NPN device or ESD lateral PNP device indicates that the transistor structure is configured to handle high-voltage transient events such as ESD strikes, and is arranged in a lateral geometry. NPN or PNP doping profiles determine the type of majority carriers (electrons for NPN, holes for PNP) responsible for conduction. As an ESD protection element, such a device can safely shunt excess charge generated by an ESD event away from sensitive circuitry, using the lateral bipolar emitter and collector structures and the carefully engineered ballasting resistance to prevent localized damage and ensure uniform current sharing.

In some embodiments, the semiconductor device is configured to control a point of breakdown, which defines a specific voltage at which the semiconductor structure transitions from a non-conducting state to a conducting state during an electrostatic event. The term “point of breakdown” refers to a junction or region within the device that establishes a repeatable and stable breakdown voltage. By controlling this point of breakdown, the device directs current flow lines through predetermined paths and ensures that ballasting resistance is applied where needed. Ballasting resistance is the intentional addition of distributed resistive elements, typically by adjusting doping levels or introducing resistive materials, to ensure that current is uniformly distributed. This uniformity is critical for preventing localized hot spots and failures in ESD conditions.

In some embodiments, incorporating ballasting in the emitter 304 and the collector 306 of the semiconductor device creates a controlled on-resistance (Ron) sufficient to enable uniform current flow within one finger of a multi-finger transistor structure, as well as from one finger to another. A finger can be one parallel unit or section of the transistor arranged alongside multiple other identical units. Without proper ballasting resistance, only a single finger can trigger during an ESD event, causing a localized failure. By ensuring that each finger includes sufficient resistance, the semiconductor device encourages all fingers to turn on simultaneously, thereby increasing the overall ESD current-handling capability and improving reliability.

In some embodiments, the semiconductor device is adaptable to various transistor configurations used for ESD protection, including a single ESD NFET, a single ESD PFET, and variations of oxide thickness, such as thin oxide or thick oxide gates. The ESD NFET can be an N-type field-effect transistor optimized for electrostatic discharge handling, while ESD PFET is the corresponding P-type version. The choice between thin oxide and thick oxide affects the device's gate dielectric properties, with thicker oxides offering potentially higher breakdown voltages but potentially slower switching.

In some embodiments, the semiconductor device can be stacked in series, forming a stacked ESD device. Stacking two or more transistors in series increases the effective breakdown voltage and helps clamp higher levels of ESD energy. A stacked ESD NFET can include multiple N-type transistors arranged vertically or horizontally in series, each possibly having any oxide thickness and any desired number of stages in the stack. Similarly, a stacked ESD PFET can include multiple P-type transistors arranged similarly. By stacking multiple devices, the total clamping voltage and current capacity can be adjusted to handle more severe ESD events.

In some embodiments, lateral bipolar embodiments are also contemplated. A lateral bipolar device can be one in which the current flow between emitter 304 and collector 306 is predominantly lateral, parallel to the wafer surface. These embodiments can include STI bound lateral NPN, STI bound lateral PNP, non-self-aligned without STI NPN, and non-self-aligned without STI PNP devices. The term “STI bound” refers to structures surrounded by shallow trench isolation, which constrains current flow in well-defined lateral paths. “Non-self-aligned” indicates that certain fabrication steps, such as doping or gate definition, are not precisely aligned through self-aligned processing methods. The choice between NPN or PNP doping, STI or non-STI structures, and self-aligned or non-self-aligned techniques provides a wide design latitude for optimizing ESD robustness, device layout, and compatibility with various integrated circuit process flows.

In some embodiments, the combination of controlled breakdown points, ballasting resistance, and various device configurations (including ESD NFET, ESD PFET, stacked arrangements, and lateral bipolar devices allows for a highly versatile ESD protection solution. By adjusting these parameters and structures, designers can ensure that the device exhibits uniform current distribution, improved triggering behavior, and robust ESD performance, ultimately leading to more reliable and compact integrated circuits capable of withstanding harsh transient conditions. FIG. 3C illustrates an I-V graph of the device shown in FIG. 3A. As can be seen, the It2 (point 354) is lowered, while the Vt2 is enhanced compared to the failure region as shown in FIG. 1C.

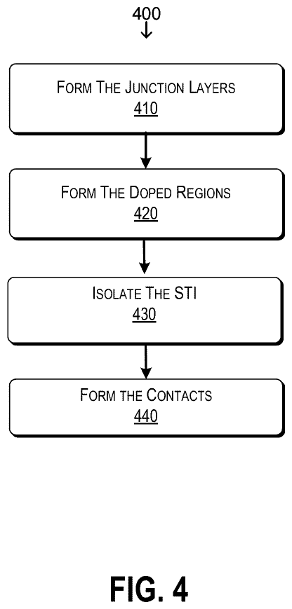

FIG. 4 illustrates a block diagram of a method 400 for forming the semiconductor device, in accordance with some embodiments. As shown by block 410, the junction layers are formed.

As shown by block 420, the doped regions are formed.

As shown by block 430, the STI is formed.

As shown by block 440, the contact are formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a base;
an emitter;
a collector between the base and the emitter;
a well region below the base, the emitter and the collector; and
an isolating layer extended horizontally and at least partially isolating the well region from the collector and the emitter.

2. The semiconductor device of claim 1, wherein the isolating layer, the well region, the collector and the emitter form a junction, wherein the junction is configured to act as at least part of a lateral bipolar emitter and lateral bipolar collector for local ballasting and series resistance.

3. The semiconductor device of claim 2, wherein the junction is further configured to be part of a source/drain region of a transistor for local ballasting and series resistance.

4. The semiconductor device of claim 1, wherein each of the base, collector and emitter comprises:
a set of gate regions;
a doped region between the set of gate regions; and
a contact over the doped region.

5. The semiconductor device of claim 1, wherein each of the base, collector and emitter further comprises a set of nanosheet channels extended horizontally across a gate region.

6. The semiconductor device of claim 5, wherein the set of nanosheet channels are made of alternating layers of silicon and silicon germanium.

7. The semiconductor device of claim 1, wherein the semiconductor device further comprises:
shallow trench isolation (STI) below gate regions of the base, collector and emitter adjacent to each other; and
a substrate below the well region.

8. The semiconductor device of claim 1, wherein the semiconductor device is an electro-static discharge (ESD) lateral NPN device, or an EDS lateral PNP device.

9. A method for fabrication of a semiconductor device, the method comprising:
forming a base;
forming an emitter;
forming a collector between the base and the emitter;
forming a well region below the base, the emitter and the collector; and
forming an isolating layer extended horizontally and at least partially isolating the well region from the collector and the emitter.

10. The method of claim 9, further comprising:
forming a junction via the isolating layer, the well region, the collector and the emitter, wherein the junction is configured to act as at least part of a lateral bipolar emitter and lateral bipolar collector for local ballasting and series resistance.

11. The method of claim 10, wherein the junction is part of a source/drain region of a transistor for local ballasting and series resistance.

12. The method of claim 9, wherein forming each of the base, collector and emitter comprises:
forming a set of gate regions;
forming a doped region between the set of gate regions; and
forming a contact over the doped region.

13. The method of claim 9, wherein forming each of the base, collector and emitter further comprises:
forming a set of nanosheet channels extended horizontally across a gate region.

14. The method of claim 13, wherein the set of nanosheet channels are made of alternating layers of silicon and silicon germanium.

15. The method of claim 9, further comprising:
forming shallow trench isolation (STI) below gate regions of the base, collector and emitter adjacent to each other; and
forming a substrate below the well region.

16. The method of claim 9, wherein the semiconductor device is an electro-static discharge (ESD) lateral NPN device, or an EDS lateral PNP device.

17. A semiconductor device, comprising:
a well region on a backside of the semiconductor device; and
an isolating layer extended horizontally and at least partially isolating the well region from a frontside of the semiconductor device, wherein the isolating layer and the well region, form a junction configured to act as at least part of a lateral bipolar emitter and lateral bipolar collector for local ballasting and series resistance.

18. The semiconductor device of claim 17, wherein the junction is further configured to be part of a source/drain region of a transistor for local ballasting and series resistance.

19. The semiconductor device of claim 17, further comprising:
a base;
an emitter; and
a collector between the base and the emitter, wherein the base, the collector and the emitter are located on the frontside of the semiconductor device.

20. The semiconductor device of claim 19, wherein each of the base, collector and emitter comprises:
a set of gate regions;
a doped region between the set of gate regions; and
a contact over the doped region.
